(19) United States
(12) Patent Application Publication
(10) Pub. No.: US 2014/0063917 A1
(43) Pub. Date: Mar. 6, 2014

(54) READ SELF-TIME TECHNIQUE WITH FINE GRAINED PROGRAMMABLE LOGIC DELAY ELEMENT

(71) Applicants: Disha Singh, Bangalore (IN); Sanjay Kumar Prajapati, Bangalore (IN)

(72) Inventors: Disha Singh, Bangalore (IN); Sanjay Kumar Prajapati, Bangalore (IN)

(73) Assignee: LSI CORPORATION, Milpitas, CA (US)

(21) Appl. No.: 13/603,141

(22) Filed: Sep. 4, 2012

(51) Int. Cl. G11C 11/00

(52) U.S. Cl. 365/154

(57) ABSTRACT

A sense amplifier enable signal delay circuit for the programmable control of the delay of the generation of a sense amplifier enable signal is described. Further, stacked transistors and a pulse-width control block, which are programmed by external test pins to control the delay of the generation of a sense amplifier enable signal are described. Methods associated with the use of the sense amplifier enable signal delay circuit and for the sense amplifier enable signal generation delay are also described.

### BACKGROUND

Static random access memory circuits are a type of random access memory circuit that stores data in a circuit such as an integrated circuit. Static random access memory circuits allow for data to be written, stored and read from memory cells in the static random access memory circuit arranged as an array of selectable rows and columns or bit lines.

### SUMMARY

An embodiment of the present invention may comprise a method for controlling the delay of a sense amplifier enable signal comprising: generating an internal clock signal from an internal clock signal generator; transmitting the internal clock signal to a delay block wherein the delay block comprises at least one n-channel metal-oxide-semiconductor stacked transistor and at least one p-channel metal-oxide semiconductor stacked transistor; and generating and transmitting a rising sense amplifier enable signal from the delay block to begin sensing data in a static random access memory circuit.

An embodiment of the present invention may further comprise a sense amplifier enable signal delay circuit comprising: an internal clock signal generator capable of generating an internal clock signal; a delay block configured to receive an internal clock signal from the internal clock signal generator wherein the delay block comprises at least one n-channel metal-oxide semiconductor stacked transistor and at least one p-channel metal-oxide semiconductor stacked transistor, wherein the at least one n-channel metal-oxide semiconductor stacked transistor and at least one p-channel metal-oxide semiconductor stacked transistor are configured to control the delay of the internal clock signal; and wherein the delay block is capable of generating and transmitting a sense amplifier enable signal from the delay block to begin sensing data in a static random access memory circuit.

### BRIEF DESCRIPTION OF THE DRAWINGS

FIG. 1 is a block diagram of a static random access memory with a delay block.

FIG. 2 is a block diagram of a control block housing a delay block and pulse-width control block.

FIG. 3 is a block diagram of a control block generating a clock reset signal.

FIG. 4 is a block diagram of a control block generating a sense amplifier enable signal.

FIG. 5 is a block diagram of a delay block and a pulse-width control block.

FIG. 6 is a block diagram of a delay block showing stacked transistor delay elements.

FIG. 7 is a block diagram of a pulse-width control block with two pulse-width control paths.

FIG. 8 is a block diagram of an n-channel metal-oxide semiconductor (“NMOS”) stacked transistor delay element.

FIG. 9 is a block diagram of a p-channel metal-oxide semiconductor (“PMOS”) stacked transistor delay element.

FIG. 10 is a flow diagram of a method of using a programmable delay block.

FIG. 11 a is a flow diagram of a method of programming a delay block using delay block external test pins.

FIG. 11b is a flow diagram of a method of programming a delay block with two delay block external test pins programmed high.

FIG. 11c is a flow diagram of a method of programming a delay block with three delay block external test pins programmed high.

FIG. 12 is a flow diagram of a method of generating a clock reset signal and generating a sense amplifier enable signal (“SAEN”) output using a delay block and pulse-with control block.

### DETAILED DESCRIPTION OF THE EMBODIMENTS

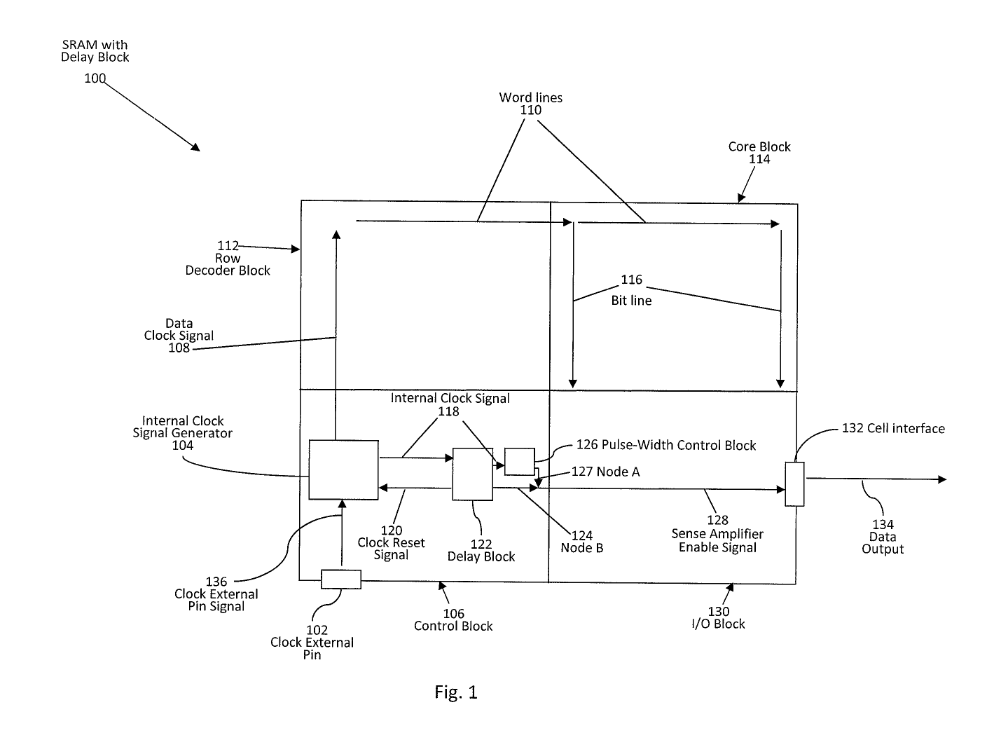

FIG. 1 is a block diagram of a static random access memory circuit with a delay block 100. As shown in FIG. 1, an internal clock signal generator 104 is located in a control block 106. The internal clock signal generator 104 receives a clock external pin signal 136 through a clock external pin 102 where the internal clock signal generator 104 generates an internal clock signal 118. The internal clock signal generator 104 also generates an active data clock signal 108, which is sent to specified word lines 110 located in a row decoder block 112 and a core block 114 and then bit lines 116 also located in the core block 114. The active data clock signal 108 sent to the word lines 110 and bit lines 116 collects information stored on word lines 110 and bit lines 116 located in the core block 114.

The internal clock signal 118 is sent from the internal clock signal generator 104 to a delay block 122. The internal clock signal 118 is programmed to go high through a series of external test pins (not shown in FIG. 1) in communication with the delay block 122 comprising a series of the stacked metal-oxide-semiconductor transistors structures within the delay block 122. Once the internal clock signal 118 has travelled through the delay block 122, the delay block 122 produces the rising edge of the internal clock signal 118 on node B 124 which is sent to a NOR gate (not shown in FIG. 1) followed by an inverter (not shown in FIG. 1) to generate the rising edge of the sense amplifier enable signal 128 which is sent to the I/O block 130. The delay block 122 also generates a clock reset signal 120.

The clock reset signal 120 generated by the delay block 122 is sent back to the internal clock signal generator 104 which makes the internal clock signal 118 go low. The internal clock signal 118 is then sent back through the delay block 122, where the internal clock signal 118 delay is not controlled by external test pins in delay block 122 but is sent on to the pulse-width control block 126. The pulse-width control block 126 delays the falling edge of the internal clock signal 118 through external test pins (not shown in FIG. 1) which control the path of the internal clock signal 118 through a series of inverters (not shown in FIG. 1). The pulse-width control block 126 then transmits the falling edge of the internal clock signal 118 on node A 127 where the signal on node A 127 and the signal on node B 124 from the delay block 122 are combined in a NOR gate (not shown in FIG. 1). The combined falling signal on node A 127 and the falling signal on node B 124 are transmitted from the NOR (not shown in FIG. 1) followed by an inverter (not shown in FIG. 1) as the sense amplifier enable signal 128 falling signal. The transmission of the falling edge of the internal clock signal 118 on node A 127 from the pulse-width control block 126 also resets the sensing operation of the circuit.

The rising edge of the internal clock signal 118 is timed or delayed in the delay block 122 and the falling edge of the internal clock signal 118 is timed or delayed in the pulse-width control block 126. The delay of the rising edge of the internal clock signal allows the rising edge of the sense amplifier enable signal 128 to be timed to converge with the data clock signal 108 or voltage that is traveling through the static random access memory circuit 100 to trigger the amplification of the data on the data bit lines 116. Once the sense amplifier enable signal 128 converges with the data clock signal 108 housing the information stored on the bit lines 116, the sense amplifier enable signal 128 begins sensing and amplifying the data travelling in the bit lines 116 into a data output 134 signal. Data output 134 is produced which is transmitted out of the static random access memory circuit 100 by a cell interface 132. The falling edge of the internal clock signal 118 through the pulse-width control block 126 allows the sense amplifier enable signal 128 to fall and reset after a desired delay or pulse-width.

As shown in FIG. 1, and further described below, the circuit 100 allows for the programmable, fine grained tuning of the sensing operation of a sense amplifier enable signal 128 through the programmable delay of the internal clock signal 118 through programmable delay elements found in the delay block 122 and pulse-width control block 126. The delay in delay block 122 can be fine-tuned to achieve delay steps less than 10 ps or so as opposed to 40 ps of conventional sense amplifier enable delay methods. The circuit in FIG. 1 eliminates the use of self-timed dummy columns and dummy rows in the static random access memory circuit 100 making the design area of the circuit efficient and less complex. The circuit shown in FIG. 1 also reduces the complexity of register files due to additional tracking rows and columns where the dummy bit lines and dummy rows are not required. The circuit shown in FIG. 1 also reduces the effect of process variations in the delay of sense amplifier enable signal 128 as compared to conventional sense amplifier enable delay scheme. The circuit shown in FIG. 1 may be integrated into a variety of integrated circuits and is used to generate an accurate sense amplifier enable signal as well as clock reset signal using fine grained tunable, programmable delay elements found in the delay block and pulse-width control block.

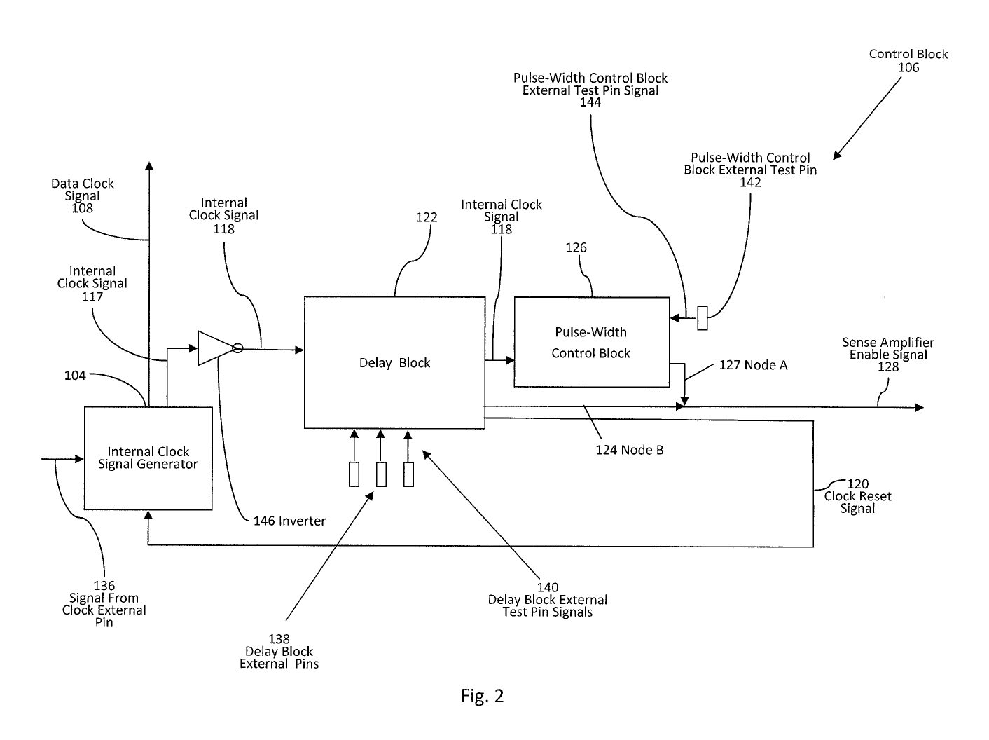

In FIG. 2, au example of the control block 106 of the disclosure is provided. As shown in FIG. 2, an internal clock signal generator 104 receives a clock external pin signal 136 from a clock external pin (not shown in FIG. 2). The internal clock signal generator 104 generates a data clock signal 108 that is sent to a row decoder block (not shown in FIG. 2) and the internal clock signal generator 104 also generates an internal clock signal 117, which is sent to an inverter 146, which inverts and then transmits the internal clock signal 118 to a delay block 122. In the delay block 122, delay block external test pins 138 are programmed to send delay block external test pin signals 140 to control the delay of the internal clock signal 118 through the delay block 122. If the internal clock signal 118 is “high” or “1” in the delay block 122, the delay block 122 will generate a clock reset signal 120, which is sent back to the internal clock signal generator 104. The delay block 122 also produces the rising edge of the internal clock signal 118 on node B 124 which is sent to a NOR gate (not shown in FIG. 2) followed by an inverter (not shown in FIG. 2) to generate the rising edge of the sense amplifier enable signal 128 which is sent to the I/O block (as shown in FIG. 1). In the I/O block the sense amplifier enable signal 128 can begin sensing data stored in the static random access memory circuit.

The clock reset signal 120 generated by the delay block 122 is sent back to the internal clock signal generator 104 which makes the internal clock signal 118 that is sent to the delay block 122 fall or go low “0”. The internal clock signal 118 will go to the delay block 122, but this time because the internal clock signal 118 is low, the delay of the internal clock signal 118 is not controlled by the delay block external test pins 138. The internal clock signal 118 passes through the delay block 122 and then enters the pulse-width control block 126. In the pulse-width control block 126, at least one pulse-width control block external test pin 142 sends a command by means of a pulse-width control block external test pin signal 144, which controls the path the internal clock signal 118 will travel through the pulse-width control 126. The pulse-width control block 126 then transmits the falling edge of the internal clock signal 118 onto node A 127 where the signal on node A 127 is combined with the falling signal on node B signal 124 from the delay block 122 in a NOR gate (not shown in FIG. 2). The combined node A falling signal 127 and node B falling signal 124 are transmitted from the NOR (not shown in FIG. 2) to an inverter (not shown in FIG. 2) as the sense amplifier enable signal 128 falling signal. The transmission of the falling edge of the sense amplifier enable signal 128 from the pulse-width control block 126 also resets the sensing operation.

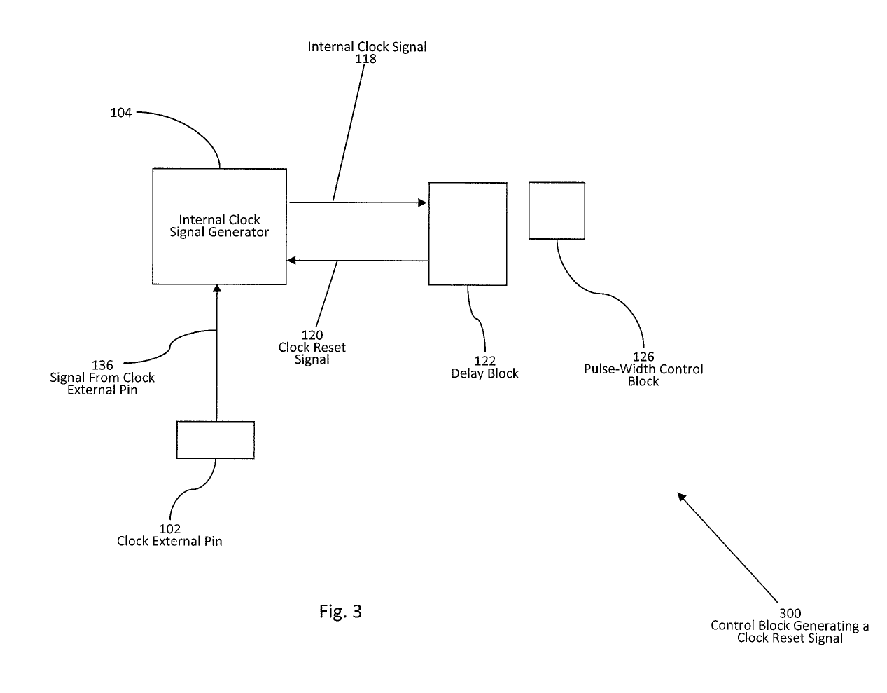

In FIG. 3, an example of a control block generating a clock reset signal 300 is provided. As shown in FIG. 3, a clock external pin 102 sends a clock external pin signal 136 to an internal clock signal generator 104. The internal clock signal generator 104 and an inverter (not shown in FIG. 3) generate a high or “1” internal clock signal 118 which is sent on to the delay block 122. The internal clock signal 118 then enters and is delayed through the delay block 122, which generates a clock reset signal 120 while also producing the rising edge of the internal clock signal 118 (not shown in FIG. 3). The rising edge of the internal clock signal 118 will then be sent out of the control block 106 as the rising edge of the sense amplifier enable signal (not shown in FIG. 3). This clock reset signal 120 is sent back to the internal clock signal generator 104, which makes the internal clock signal 118 sent to the delay block 122 fall or go in the low phase “0”. Now the internal clock signal 118 is sent through the delay block 122 with fixed delay, as the controllable delay elements do not come in the reset path, and thereafter the internal clock signal 118 is sent on to the pulse-width control block 126.

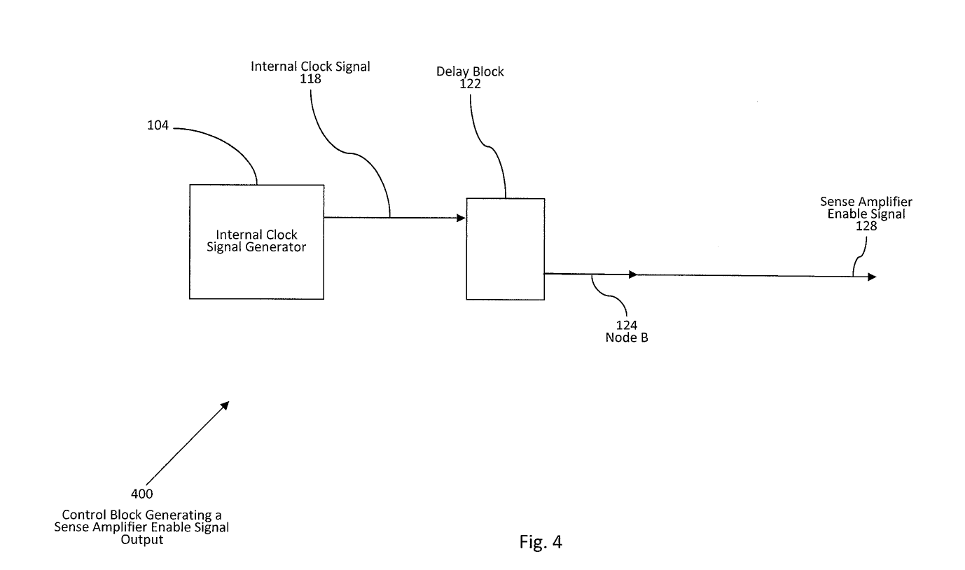

In FIG. 4, an example of a control block generating the rising edge of a sense amplifier enable signal 400 is provided. As shown in FIG. 4, an internal clock signal generator 104 generates a high or “1” internal clock signal 118 which is sent to the delay bloc 122, after sending the internal clock signal 118 through an inverter (not shown in FIG. 4). Because the internal clock signal 118 is now in the rising or high phase “1” the delay block 122 controls the delay of the internal clock signal 118. When the internal clock signal 118 has travelled through the delay block 122, the delay block 122 produces the rising edge of the internal clock signal 118 on node B 124 which is sent to a NOR gate (not shown in FIG. 4) followed by an inverter (not shown in FIG. 4) to generate the rising edge of the sense amplifier enable signal 128 which is sent to the I/O block (as shown in FIG. 1). When the internal clock signal 118 is in the rising or high phase, the delay block 122 will also produce the clock reset signal (not shown in FIG. 4).

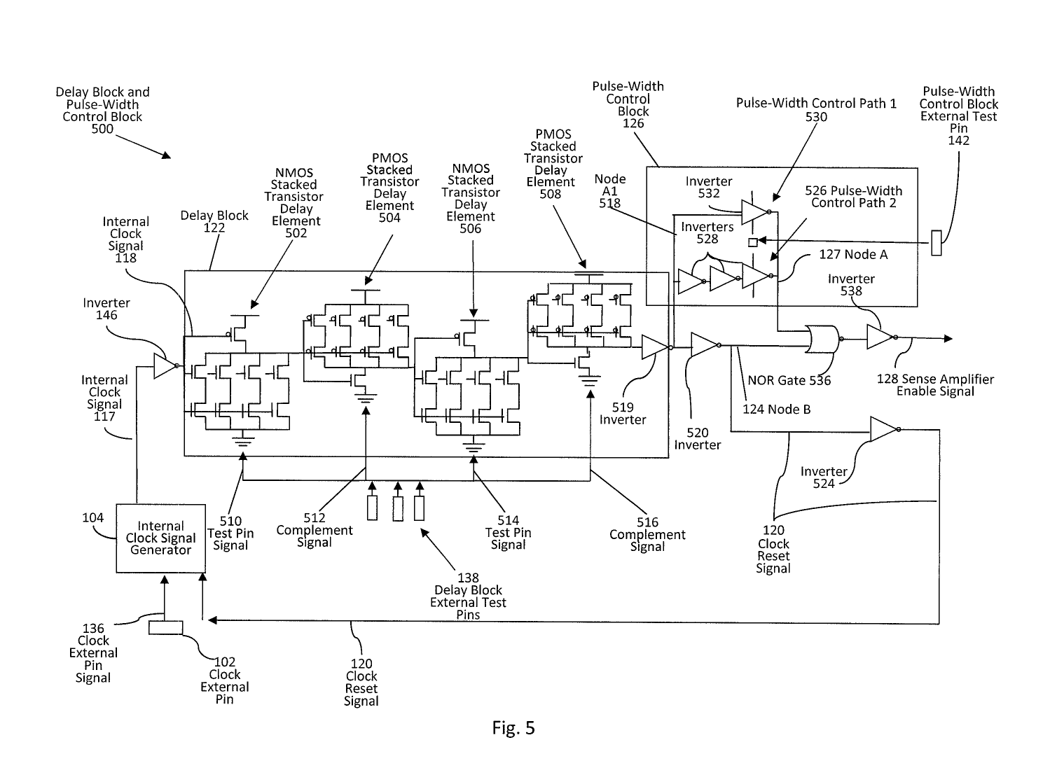

In FIG. 5, an example of the components of the delay block and pulse-width control block 500 is provided. As shown in FIG. 5, a clock external pin 102 generates a clock external pin signal 136 which is transmitted to an internal clock signal generator 104, which causes the clock to generate an internal clock signal 117, which passes through an inverter 146 where the internal clock signal 118 is sent to a delay block 122. The internal clock signal 118 enters the delay block 122 in the rising phase, where, because the internal clock signal 118 is in the rising phase, the internal clock signal 118 proceeds to an n-channel metal-oxide semiconductor (“NMOS”) stacked transistor delay element 502.

As further shown in FIG. 5, each NMOS stacked transistor elements 502 and 506 have four branches, which correspond to commands from three delay block external test pins 138. The delay block external test pins 138 control the number of branches of the NMOS stacked transistor delay elements 502 and 506 that contribute to control the delay of the internal clock signal 118. When all the delay block external test pins 138 are in a low state or “0” only one branch of series NMOS stacked transistor delay elements 502 and 506 provides current to discharge out. As a delay block external test pins 138 goes high or “1” the corresponding branch of the NMOS stacked transistor delay elements 502 and 506 starts contributing current to discharging (or charging) of the out of the internal clock signal 118. Due to increase in current, the slope of the out of the internal clock signal 118 improves. The delay of the internal clock signal 118 is modified by controlling the slope of the out of the internal clock signal 118 of the NMOS stacked transistor delay element 502 and 506. The NMOS stacked transistor delay elements 502 and 506 and the load on internal clock signal 118 out can be designed according to the step delay required. An example of the programmable control of the delay of the internal clock signal 118 is where one delay block external test pin 138 sends a delay block external test pin signal 510 or 514 to the NMOS stacked transistor delay element, where one delay block external test pin 138 is programmed to be high or “1” while the remaining two external test pins 138 are programmed to be low or “0”. The programming of one external test pin 138 to be high allows two branches of the NMOS stacked transistor delay elements 502 and 506 to contribute to the control of the delay of the internal clock signal 118. If two external test pins 138 are programmed to be high “1”, while one external test pin 138 is programmed low, then three branches of the NMOS stacked transistor delay element 502 and 506 contribute to the control of the delay of the internal clock signal 118. While three external test pins 138 are shown in FIG. 5, any number of external test pins and their combinations can be used in order to correspond with the appropriate number of stacked transistor delay elements. Therefore, while this descriptive example has three delay block external test pins 138 as shown in FIG. 5, it should be understood that this description is applicable to any such system with other numbers of delay block external test pins, as will be understood by one skilled in the art, once they understand the principles of this invention.

As shown in FIG. 5, once the rising internal clock signal 118 has travelled through the NMOS stacked transistor delay element 502, the internal clock signal 118 is transmitted to a p-channel metal-oxide semiconductor (“PMOS”) stacked transistor delay element 504 and 508. The PMOS stacked transistor delay element 504 and 508 has four branches, which control the delay of the internal clock signal 118 based on commands from complement signals 512 or 516 from the delay block external test pins 138, which correspond to the test pin signals 510 or 514 controlling the NMOS stacked transistor delay elements 502 and 506. The complement signals 512 or 516 from the delay block external test pins 138 control the number of branches of the PMOS stacked transistor delay elements 504 and 508 that contribute to control the delay in the internal clock signal 118. When all the delay block external test pins 138 are in a low state or “0” only one branch of series PMOS stacked transistor delay elements provides current to discharge the internal clock signal 118 out. As a delay block external test pins 138 goes high or “1” the corresponding branch of the PMOS stacked transistor delay element starts contributing current to discharging (or charging) of the internal clock signal 118 out node. Due to increase in the internal clock signal 118 current the slope of the out improves. So the delay of the internal clock signal 118 is modified by controlling the slope of the out signal of the PMOS stacked transistor delay element 504 and 508. The PMOS stacked transistor delay element 504 and 508 and the load on the out of the internal clock signal 118 can be designed according to the step delay required for the internal clock signal 118. A further example of the programmable control of the delay of the internal clock signal 118 is where one delay block external test pin 138 is programmed to be high while the remaining two delay block external test pins 138 are programmed to be low. The delay block external test pins 138 send the complement signals 512 or 516 to the corresponding PMOS stacked transistor delay element, which allows two branches of the PMOS stacked transistor delay element 504 or 508 to contribute to the control of the delay of the internal clock signal 118. If two delay block external test pins 138 are programmed to be high, while the remaining external test pin 138 is programmed low, then complement signals 512 and 516 then three branches of the PMOS stacked transistor delay element 504 or 508 contribute to the control of the delay of the internal clock signal 118.

In the example shown in FIG. 5, two NMOS stacked transistor delay elements 502 and 506 and two PMOS stacked transistor delay elements 504 and 508 are illustrated but any number of NMOS and PMOS stacked transistor delay elements can be used. Therefore, while this descriptive example has two NMOS stacked transistor delay elements 502 and 506 and two PMOS stacked transistor delay elements 504 and 508, it should be understood that this description is applicable to any such system with other numbers of NMOS and PMOS stacked transistor delay elements, as will be understood by one skilled in the art, once they understand the principles of this invention.

In addition, the delay block external test pins 138 shown in FIG. 5 can be programmed to provide separate commands to each NMOS stacked transistor delay element 502 and 506 and each PMOS stacked transistor delay element 504 and 508. As an example, this allows an external source to program one NMOS or PMOS stacked transistor delay element to have three branches contribute to the internal clock signal 118 delay, while programming another NMOS or PMOS stacked transistor delay element to have two branches contribute to the delay of the internal clock signal 118. This allows for additional fine tuning of the delay of the internal clock signal 118.

As further shown in FIG. 5, an external source is able to program the stacked transistor delay elements in a variety of ways such as programming one NMOS stacked transistor delay element to have one branch contribute to the internal clock signal 118 delay, while separately programming the corresponding PMOS stacked transistor delay element to have two branches contribute to the delay of the internal clock signal 118. This allows for additional fine tuning of the delay of the internal clock signal 118 and the generation of the sense amplifier enable signal 128.

As shown in FIG. 5, the internal clock signal 118 travels through each NMOS stacked transistor delay element 502 and 506 and then on to the corresponding PMOS stacked transistor delay element 504 and 508. Once the internal clock signal 118 has travelled through the delay block 122 the internal clock signal 118 passes through an inverter 517, where the rising edge of the internal clock signal 118 is produced and transmitted onto node B 124. The rising signal on node B 124 is sent on to a NOR gate 536 and on to another inverter 538 which generates the rising edge of the sense amplifier enable signal 128. The rising edge of the sense amplifier enable signal 128 is sent to the I/O block (as shown in FIG. 1).

After the rising edge of the internal clock signal 118 passes through the inverter 519 in the delay block 122, the delay block 122 also generates a clock reset signal 120. The clock reset signal 120 generated by delay block 122 passes through two additional inverters 520 and 524 and is sent back to the internal clock signal generator 104, which makes the internal clock signal 118 fall or go low. The falling internal clock signal 118 is then sent back through the delay block 122, where the internal clock signal 118 is not delayed but passes through an inverter 519 is sent onto node A1 518, where the signal on node A1 518 is sent to the pulse-width control block 126.

As further shown in FIG. 5, when a signal on Node A1 518 goes high (which is the result of internal clock signal 118 going low) the signal is sent to the pulse-width control block 126 where a pulse-width control block external test pin 142 determines the internal clock signal's 118 path through the pulse-width control block 126. If the external test pin 142 is high (logic state “1”) then pulse-width control path 2 526 is selected and three inverters 528 are used to control the pulse-width of the internal clock signal 118 by delaying the falling edge of the internal clock signal 118. If the external test pin 142 is low (logic state “0”) then pulse-width control path 1 530 is selected and one inverter 532 is used to control the pulse-width of the internal clock signal 118 by delaying the falling edge of the internal clock signal 118. After passing through either pulse-width control path 1 530 or pulse-width control path 2 526, the internal clock signal 118 enters node A 127 as a low signal. The node A signal 127 then transmits the falling edge of the internal clock signal 118 where the falling edge of the node A signal 127 and the falling edge of the node B signal 124 from the delay block 122 are combined in a NOR gate 536. The combined node A falling signal 127 and node B falling signal 124 are transmitted from the NOR gate 536 to an inverter 538 as the sense amplifier enable signal 128 falling signal. The transmission of the falling edge of the sense amplifier enable signal 128 resets the sensing operation of the circuit. Therefore, the reset of internal clock signal 118 initiates reset (logic “0”) of the falling edge of the sense amplifier enable signal 128 as determined by the pulse-width control block 126 after the signal has passed through either pulse-width control path 1 or path 2.

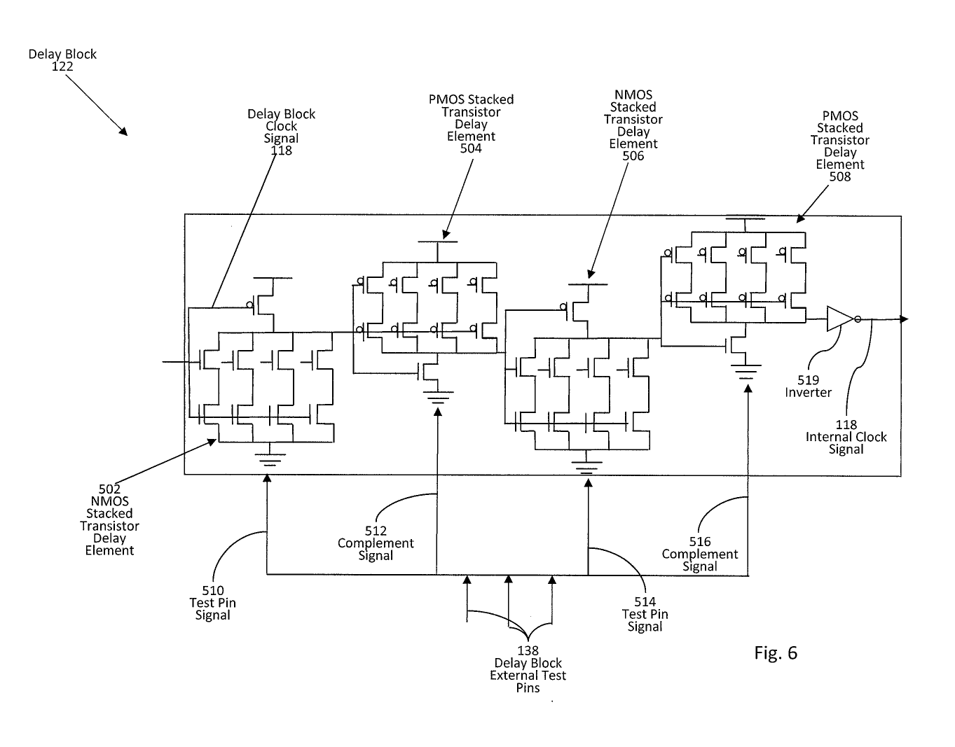

FIG. 6 is an example of a delay block 122 of the disclosure. As shown in FIG. 6, an internal clock signal 118 enters the NMOS stacked transistor delay element 502. The number of channels in the NMOS stacked transistor delay element 502 available to control the delay of the internal clock signal 118 is controlled by test pin signals 510 from the delay block external test pins 138. Once the internal clock signal 118 passes through the first NMOS stacked transistor delay element 502, the internal clock signal 118 enters the PMOS stacked transistor delay element 504 where the delay of the internal clock signal 118 is controlled by the delay block external test pins 138 through a complement signal 512 In FIG. 6, once the internal clock signal 118 has travelled through the first PMOS stacked transistor delay element 504, the internal clock signal 118 enters a second NMOS stacked transistor delay element 506 where the delay of the internal clock signal 118 is again controlled by the delay block external test pins 138 through a test pin signal 514. Finally, in FIG. 6, after passing through the second NMOS stacked transistor delay element 506, the internal clock signal 118 enters a second PMOS stacked transistor delay element 508 where the delay of the internal clock signal 118 is again controlled by the delay block external test pins 138 by means of a complement signal 516 sent from the delay block external test pins 138 to the PMOS stacked transistor delay element 508. The delay block 122 is applicable for all the applications including write self-time delay/pulse-width tracking that needs fine grained delay control to tune the write margin without impacting the performance

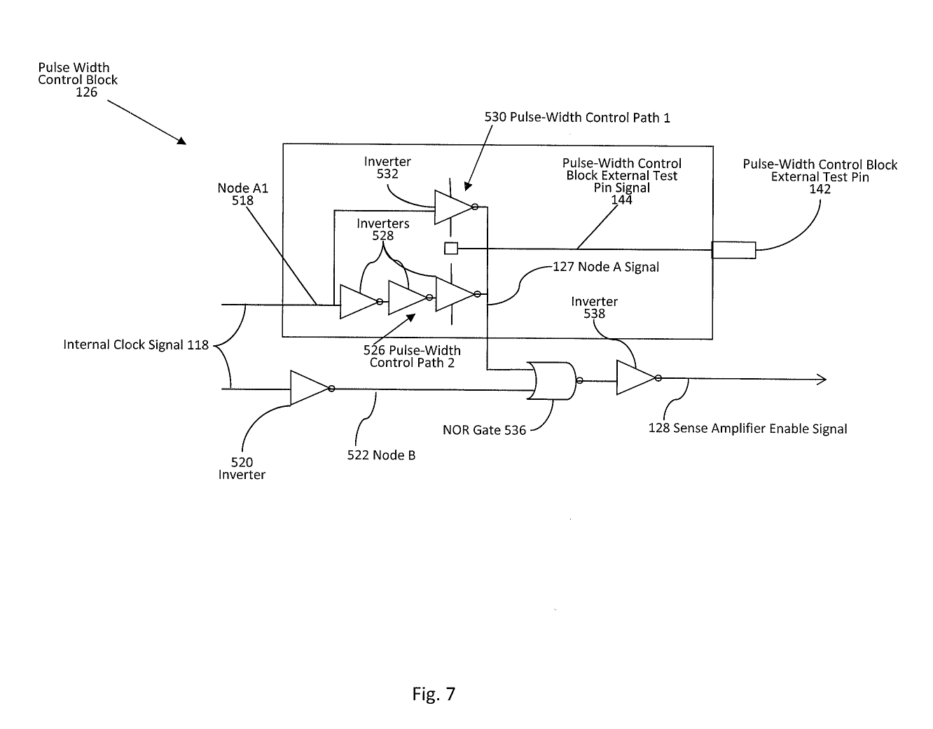

FIG. 7 is an example of the pulse-width control block 126. As shown in FIG. 7, the falling edge of the internal clock signal 118, which has exited the delay block (not shown in FIG. 7) is sent to Node A1 518 and a second internal clock signal 118 is sent through an inverter 520 and on to Node B 522. The internal clock signal 118 on Node A1 518 goes high (which is the result of internal clock signal 118 going low) and the signal is sent to the pulse-width control block 126 where a pulse-width control block external test pin 142 determines the internal clock signal's 118 path through the pulse-width control block 126. If the external test pin 142 is high (logic state “1”) then pulse-width control path 2 526 is selected and three inverters 528 are used to control the pulse-width of the internal clock signal 118 by delaying the falling edge of the internal clock signal 118. If the external test pin 142 is low (logic state “0”) then pulse-width control path 1 530 is selected and one inverter 532 is used to control the pulse-width of the internal clock signal 118 by delaying the falling edge of the internal clock signal 118. After passing through either pulse-width control path 1 530 or pulse-width control path 2 526, the internal clock signal 118 enters Node A 127 as a low signal. The falling edge signal on Node A signal 127 is then combined in a NOR gate 536 with the falling edge signal on node B from the delay block 122. The combined node A falling signal 127 and node B falling signal 124 are transmitted from the NOR gate 536 to an inverter 538 as the sense amplifier enable signal 128 falling signal. The transmission of the falling edge of the sense amplifier enable signal 128 resets the sensing operation of the circuit.

In the example shown in FIG. 7, two pulse-width control paths are illustrated but any number of pulse-width control paths can be used. Therefore, while this descriptive example has two pulse-width control paths, it should be understood that this description is applicable to any such system with other numbers of pulse-width control paths, as will be understood by one skilled in the art, once they understand the principles of this invention.

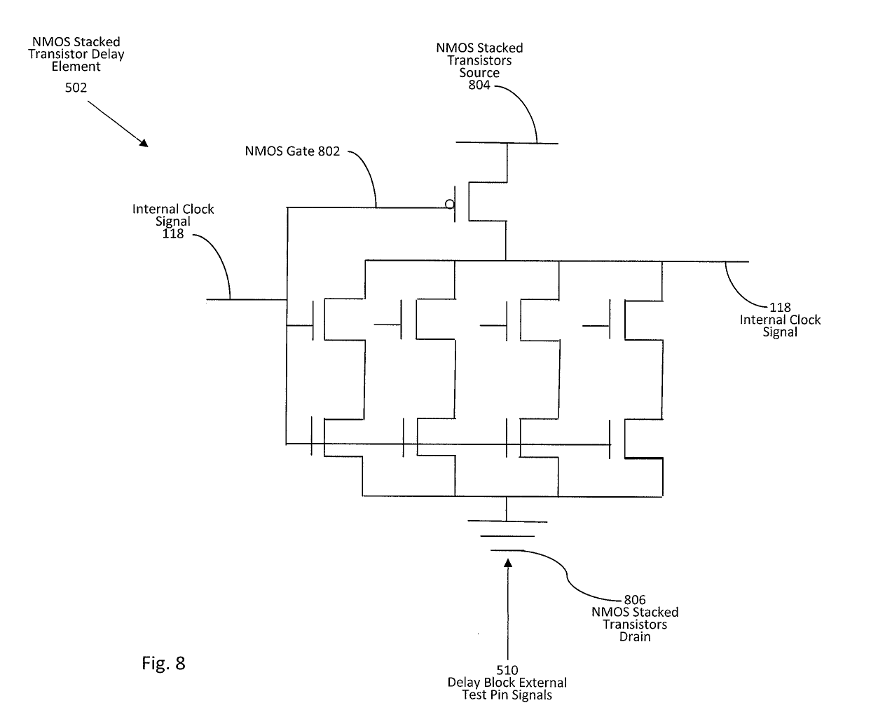

In FIG. 8 an NMOS stacked transistor delay element 502 is shown. As shown in FIG. 8, the internal clock signal 118 enters the NMOS stacked transistor delay element 502. The internal clock signal 118 enters the NMOS stacked transistor delay element 502 through the NMOS gate 802 where the internal clock signal 118 flows between the NMOS stacked transistor source 804 and the NMOS stacked transistor drain 806 terminals. Three external test pins 138, as shown in FIG. 2 and FIG. 5, send delay block external test pins signals 510 that control the number of branches or channels of the NMOS stacked transistor delay element 502 that contribute to control the delay in the internal clock signal 118. Once the internal clock signal 118 has passed through the branches of the NMOS stacked transistor delay element 502, the internal clock signal 118 passes out of the NMOS stacked transistor delay element 502.

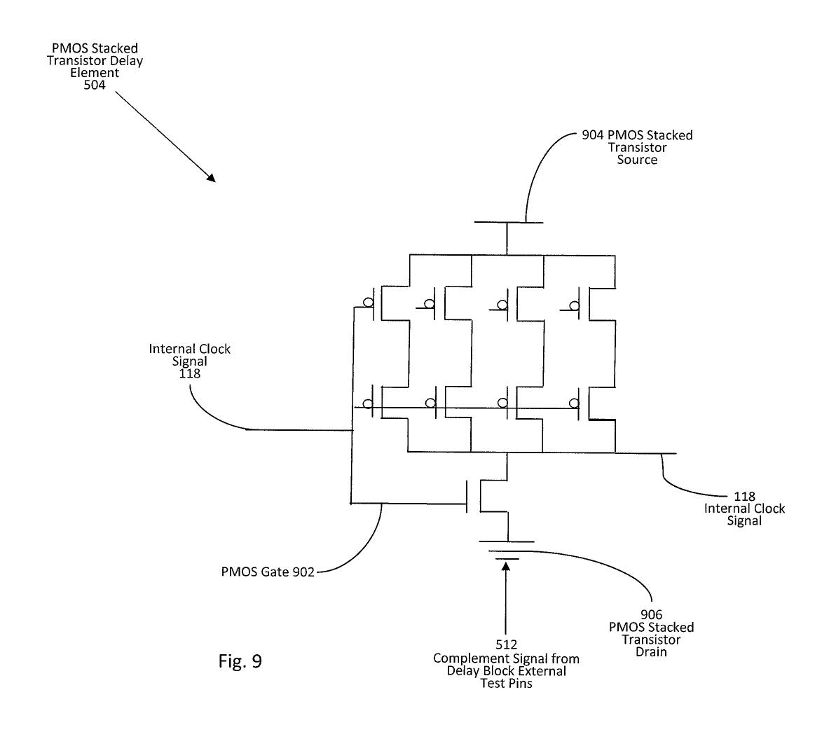

In FIG. 9, a PMOS stacked transistor delay element 504 is shown. As shown in FIG. 9, the internal clock signal 118 enters the PMOS stacked transistor delay element 504. The internal clock signal 118 enters the PMOS stacked transistor delay element 504 through the PMOS gate 902 where the internal clock signal 118 flows between the PMOS stacked transistor source 904 and the PMOS stacked transistor drain 906 terminals. Three delay block external test pins 138, shown in FIG. 2 and FIG. 5, send a complement signal 512, which controls the number of branches or channels of the PMOS stacked transistor delay element 504 that contribute to control the delay in the sense amplifier enable input signal 128. Once the internal clock signal 118 has passed through the branches of the PMOS stacked transistor delay element 504, the internal clock signal 118 passes out of the PMOS stacked transistor delay element 504.

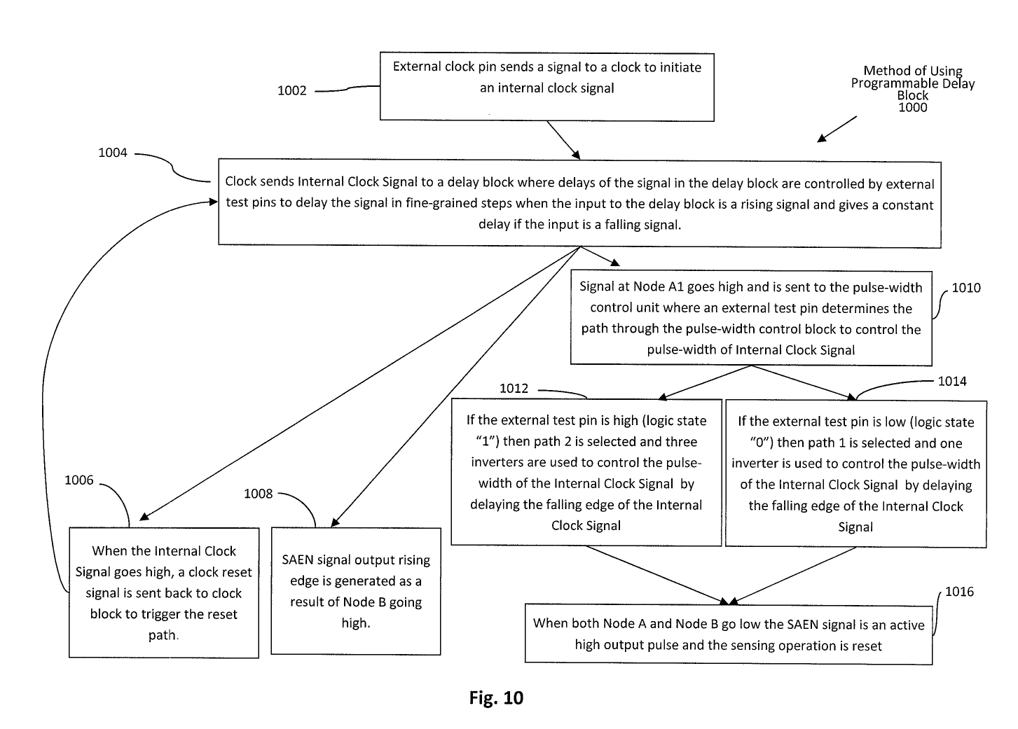

FIG. 10 is a flow diagram of a method of using a programmable delay block with a pulse-width control block 1000. As shown in FIG. 10, in step 1002 a clock external pin sends a signal to an internal clock signal generator to initiate a data clock signal and an internal clock signal. In step 1004, the clock sends a rising internal clock signal to a delay block. Delays of the rising internal clock signal in the delay block are controlled by external test pins in communication with stacked transistor delay elements to determine the number of branches of the NMOS and PMOS stacked transistors that contribute to delay in fine-grained steps when the input to the delay block is a rising signal. The delay block generates a constant delay if the internal clock signal is a falling signal. In step 1006, when the internal clock signal goes high out of the delay block, a clock reset signal is sent back to the internal clock generator to trigger the sense amplifier enable signal reset path and step 1004 is repeated. In step 1008, when the internal clock signal goes out of the delay block, the sense amplifier enable signal rising edge is also generated as a result of Node B going high and the rising edge of the sense amplifier enable signal is sent to an I/O block to begin sensing operations. In step 1010, when the internal clock signal entering the delay block goes low, the falling edge of the internal clock signal exits the delay block and is sent on Node A1 and on to the pulse-width control block. On Node A1, an external test pin determines the falling edge internal clock signal's path through the pulse-width control block in order to control the pulse-width of the internal clock signal. In step 1012, if the external test pin for the pulse-width control block is high (logic state “1”) then pulse-width control path 2 is selected and three inverters are used to control the pulse-width of the internal clock signal by delaying the falling edge of the internal clock signal. In step 1014, if the external test pin for the pulse-width control block is low (logic state “0”) then pulse-width control path 1 is selected and one inverter is used to control the pulse-width of the internal clock signal by delaying the falling edge of the internal clock signal. In step 1016, when the internal clock signal is low an output pulse is sent from the pulse-width control block and the falling edge of the sense amplifier enable signal is generated by the sense amplifier enable signal generator as soon as the Node A signal goes low and the Node B goes low and the sensing operation is reset.

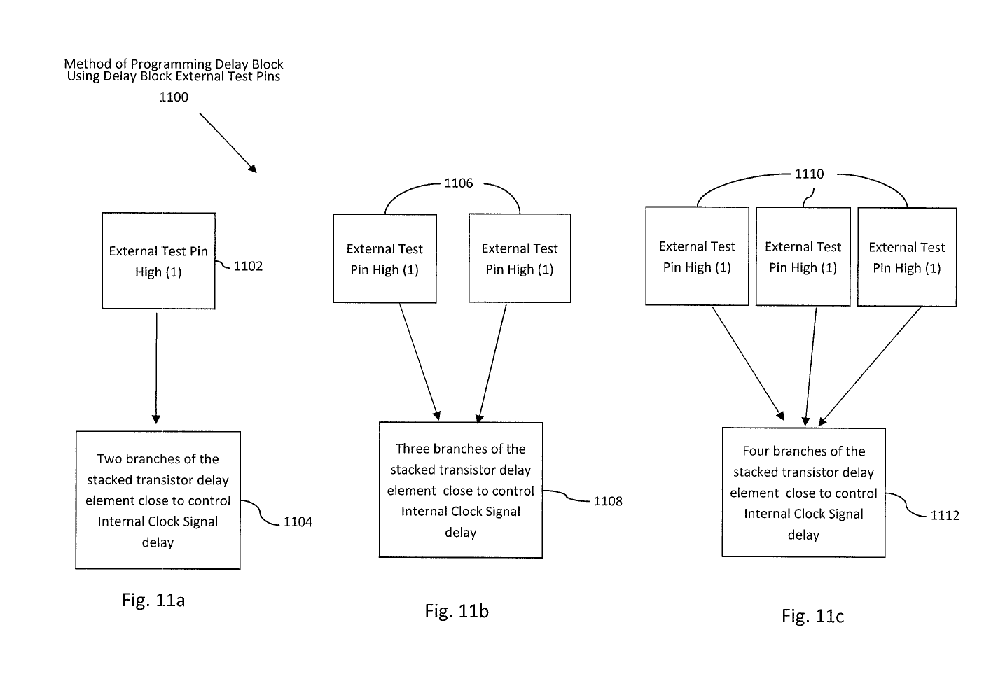

FIG. 11a is a flow diagram showing the method of programming the delay block using external test pins 1100. As shown in step 1102, one external test pin is set high or “1”. In step 1104, because only one external test pin is high, then two branches of the NMOS or PMOS stacked transistor delay element contribute to control the delay of the internal clock signal as the signal flows between the stacked transistor delay element source and the stacked transistor delay element drain.

FIG. 11b is a second flow diagram showing the method of programming the delay block using external test pins 1100. As shown in step 1106, two external test pins are high (“1”). In step 1108, because two external test pins are high, then three branches of the NMOS or PMOS stacked transistor delay element contribute to control the delay in the internal clock signal.

FIG. 11c is another flow diagram showing the method of programming the delay block using external test pins 1100. As shown in step 1110, three external test pins are high (“1”). In step 1112, because three external test pins are high, then four branches of the NMOS or PMOS stacked transistor delay element contribute to control the delay in the internal clock signal.

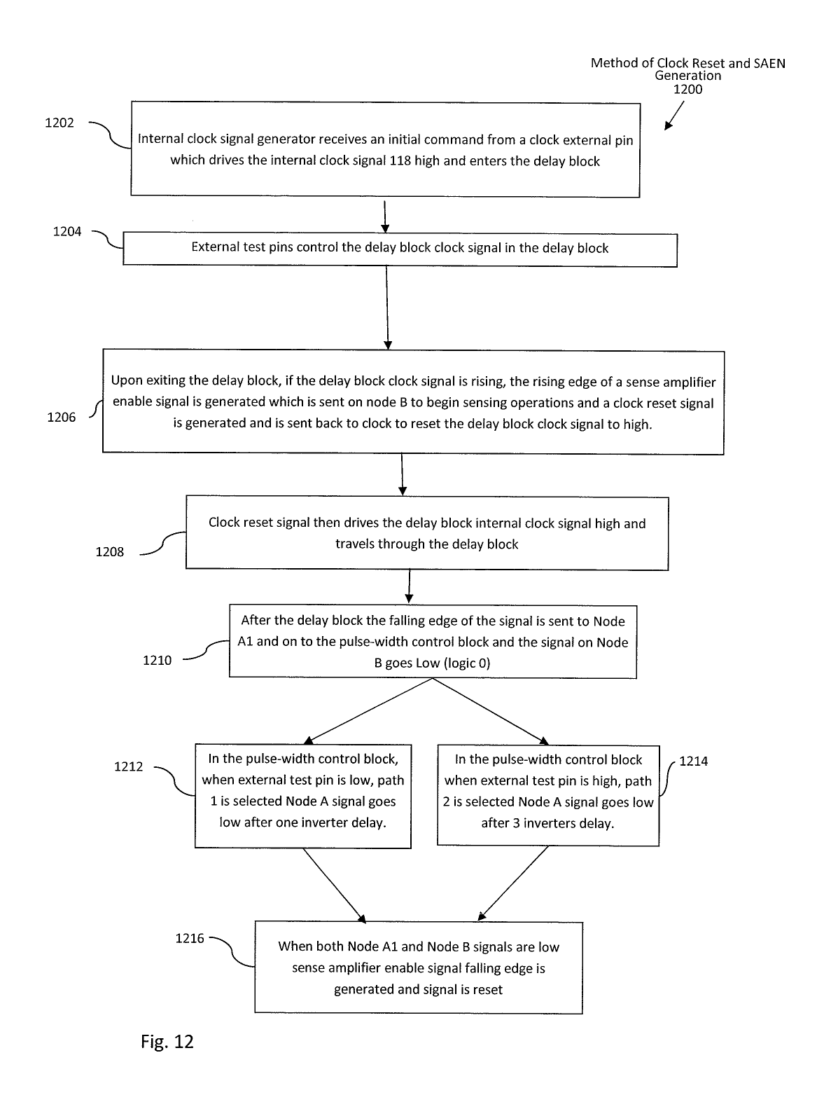

FIG. 12 is a flow diagram showing the method of clock reset and sense amplifier enable signal generation using a delay block and pulse-width control block 1200. As shown in step 1202, an internal clock signal generator receives an initial command from a clock external pin, which causes the internal clock signal generator to generate a delay block clock signal that is initially low. This internal clock signal is then inverted by an inverter driving internal clock signal high or rising and the rising internal clock signal is sent to a delay block. In step 1204, when the internal clock signal is rising, external pins control the delay of the internal clock signal in the delay block. In step 1206, upon exiting the delay block, if the internal clock signal is rising, the rising edge of the sense amplifier enable signal is generated and sent out of the control block and into the I/O block to begin sensing operations of bit lines. In addition, when the internal clock signal is rising, the delay block generates a clock reset signal, which is sent back to clock and triggers the clock reset path. The reset of delay clock block signal initiates reset (logic “0”) of the sense amplifier enable signal as determined by the pulse-width control block where the signal on Node A is high after the signal has passed through either pulse-width control path 1 or path 2. In step 1208, the clock reset signal then drives the internal clock signal generator to generate the internal clock signal high, which travels through the inverter and onto the delay block and this time the delay of the internal clock signal is constant and not controlled by external test pins. In step 1210, after travelling through the delay block, the falling edge of the internal clock signal is sent to Node A1 and on to the pulse-width control block and the internal clock signal on Node B goes low (logic 0). In step 1212, when an external test pin controlling the pulse-width control block is low, then pulse-width control path 1 through the pulse-width control block is selected and the falling edge of the internal clock signal on node A goes low after one inverter delay. In step 1214, when the external test pin controlling the pulse-width control block is high, then pulse-width control path 2 through the pulse-width control block is selected and the falling edge of the internal clock signal on node A goes low after three inverter delays. In step 1216 when both the falling edge of the internal clock signals on Node A and Node B are low, then the falling edge of the sense amplifier enable signal is generated and sensing operations are reset.

The foregoing description of the invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1. A method for controlling the delay of a sense amplifier enable signal comprising:
generating an internal clock signal within an internal clock signal generator;
transmitting said internal clock signal from said internal clock signal generator to a delay block wherein said delay block comprises at least one n-channel metal-oxide semiconductor stacked transistor and at least one p-channel metal-oxide semiconductor stacked transistor; and
generating a rising sense amplifier enable signal from said delay block and transmitting said sense amplifier enable signal to begin sensing data in a random access memory circuit.

2. The method of claim 1 further comprising:
connecting at least one delay block external test pin to said delay block;
transmitting a command from said at least one delay block external test pin to said at least one n-channel metal-oxide semiconductor stacked transistor;
closing at least one branch in said at least one n-channel metal-oxide semiconductor stacked transistor to control said delay of said internal clock signal;
transmitting a complement signal command from said at least one delay block external test pin to said at least one p-channel metal-oxide semiconductor stacked transistor; and
closing at least one branch in said at least one p-channel metal-oxide semiconductor stacked transistor to control said delay of said internal clock signal.

3. The method of claim 2, further comprising:
generating a clock reset signal from said delay block and transmitting said clock reset signal from said delay block to said internal clock signal generator, wherein said internal clock signal generator receives said clock reset signal and generates a falling edge internal clock signal;
transmitting said falling edge internal clock signal to said delay block, wherein said delay block transmits said falling edge internal clock signal to a pulse-width control block; and
generating a falling sense amplifier enable signal to reset the sense amplifier enable signal.

4. The method of claim 3, further comprising:
connecting at least one external test pin to said pulse-width control block, wherein said pulse-width control block contains at least two pulse-width control paths; and
transmitting a command from said at least one external test pin to said pulse-width control block, wherein said command from said external test pin determines the pulse-width control path said falling edge internal clock signal travels through said pulse-width control block.

5. The method of claim 1, further comprising:
generating said internal clock signal from said internal clock signal generator, wherein said internal clock signal generator receives input signals from a clock external pin.

6. The method of claim 5, further comprising:
generating said clock reset signal from the rising edge of said internal clock signal produced from said delay block; and
transmitting said clock reset signal from said delay block to said internal clock signal generator.

7. The method of claim 1, wherein said delay is less than 10 ps.

8. A sense amplifier enable signal delay circuit comprising:
an internal clock signal generator capable of generating an internal clock signal;
a delay block configured to receive an internal clock signal from said internal clock signal generator wherein said delay block comprises at least one n-channel metal-oxide semiconductor stacked transistor and at least one p-channel metal-oxide semiconductor stacked transistor, wherein said at least one n-channel metal-oxide semiconductor stacked transistor and at least one p-channel metal-oxide semiconductor stacked transistor are configured to control the delay of said internal clock signal; and
wherein said delay block is capable of generating and transmitting a rising sense amplifier enable signal from said delay block to begin sensing data in a random access memory circuit.

9. The sense amplifier enable signal delay circuit of claim 8, further comprising a pulse-width control block configured to receive an internal clock signal from said delay block, wherein said pulse-width control block comprises two or more pulse-width control paths configured to control the delay of said internal clock signal.

10. The sense amplifier enable signal delay circuit of claim 9, where said pulse-width control block is capable of generating and transmitting a falling internal clock signal that is capable of combining with a falling internal clock signal from said delay block to generate a falling sense amplifier enable signal.

11. The sense amplifier enable signal delay circuit of claim 10 further comprising at least one delay block external test pin, wherein said at least one delay block external test pin is capable of transmitting a command to said at least one n-channel metal-oxide semiconductor stacked transistor and a complement signal to said at least one p-channel metal-oxide semiconductor stacked transistor.

12. The sense amplifier enable signal delay circuit of claim 11 further comprising at least one external test pin connected to said pulse-width control block, wherein said at least one external test pin connected to said pulse-width control block is capable of transmitting a command to said pulse-width control block, wherein said command to said pulse-width control block determines the pulse-width control path of internal clock signal travels through said pulse-width control block.

13. A system for controlling sense amplifier enable signal delay within a static random access memory circuit comprising:
a delay block comprising at least one n-channel metal-oxide semiconductor stacked transistor and at least one p-channel metal-oxide semiconductor stacked transistor;
an internal clock signal generator capable of generating an internal clock signal wherein said internal clock signal is transmitted to said delay block; and
wherein said delay block is capable of generating a sense amplifier enable signal.

14. The system of claim 13, wherein said delay block generates a clock reset signal when said internal clock signal in said delay block is rising; wherein said clock reset signal is transmitted to said internal clock signal generator.

15. The system of claim 13, wherein said delay block is in communication with at least one delay block external test pin wherein said at least one delay block external test pin sends a command which controls the delay of said internal clock signal through said delay block.

16. The system of claim 13, further comprising a pulse-width control block comprising at least two pulse-width control paths.

17. The system of claim 16, wherein said pulse-width control block is in communication with an external test pin wherein said external test pin sends a command which determines the pulse-width control path said internal clock signal will travel through said pulse-width control block.

18. The system of claim 13, wherein said internal clock signal delay is less than 10 ps.

19. The system of claim 13, wherein said static random access memory circuit is integrated into an integrated circuit.
